(19) United States
(12) Patent Application Publication
(10) Pub. No.: US 2026/0341336 A1
(43) Pub. Date: Oct. 29, 2026

(54) SEMICONDUCTOR DEVICE HAVING PLURAL WORD LINES

(71) Applicant: Micron Technology, Inc., Boise, ID (US)

(72) Inventors: Mamoru Nishizaki, Yokohama (JP); Shinichi Miyatake, Sagamihara-shi (JP); Kenji Asaki, Sagamihara-shi (JP)

(73) Assignee: Micron Technology, Inc., Boise, ID (US)

(21) Appl. No.: 19/652,358

(22) Filed: Apr. 20, 2026

Related U.S. Application Data
(60) Provisional application No. 63/794,107, filed on Apr. 24, 2025.

(51) Int. Cl. G11C 11/408; G11C 5/06; G11C 11/4091; H10B 12/00

(52) U.S. Cl. CPC G11C 11/4085; G11C 5/063; G11C 11/4091; H10B 12/482; H10B 12/488; H10B 12/50

(57) ABSTRACT

An example apparatus includes a plurality of memory mats each including a plurality of word lines extending in a first direction, a plurality of digit lines extending in a second direction perpendicular to the first direction, and a plurality of memory cells each located at an intersection of an associated one of the plurality of word lines and an associated one of the plurality of digit lines. The plurality of memory mats include a first memory mat located at one end in the second direction. The plurality of word lines in the first memory mat include a first dummy word line. The example apparatus further includes a measurement circuit coupled to one end of the first dummy word line and another end of the first dummy word line and configured to measure a resistance value of the first dummy word line.

### CROSS-REFERENCE TO RELATED APPLICATIONS

This application claims the filing benefit of U.S. Provisional Application No. 63/794,107, filed Apr. 24, 2025. This application is incorporated by reference herein in its entirety and for all purposes

### BACKGROUND

A semiconductor memory device such as a DRAM includes a plurality of memory cells each located at an intersection between an associated one of word lines and an associated one of digit lines. Since recent semiconductor memory devices are considerably highly integrated, manufacturing variations in the wiring resistance of the word lines are sometimes non-negligible. Accordingly, a semiconductor memory device where the wiring resistance of word lines can be actually measured has been demanded.

### BRIEF DESCRIPTION OF THE DRAWINGS

FIG. 1A is a schematic diagram showing a layout of a semiconductor memory device according to one embodiment of the present disclosure;

FIG. 1B is a schematic enlarged view of a region A shown in FIG. 1A.;

FIGS. 2A and 2B are schematic enlarged views of a region B shown in FIG. 1B;

FIG. 3A is a schematic enlarged view for explaining a structure of a memory mat in more detail;

FIG. 3B is a circuit diagram of a unit cell included in the memory mat;

FIG. 4 is a schematic diagram for explaining dummy word lines included in the memory mats in more detail;

FIG. 5A is a schematic plan view showing contact electrodes allocated to the word lines and the dummy word lines;

FIG. 5B is a schematic sectional view along a line A-A shown in FIG. 5A;

FIG. 6 is a circuit diagram of a measurement circuit; and

FIG. 7 is a schematic diagram showing one example of circuits connected to the dummy word lines.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

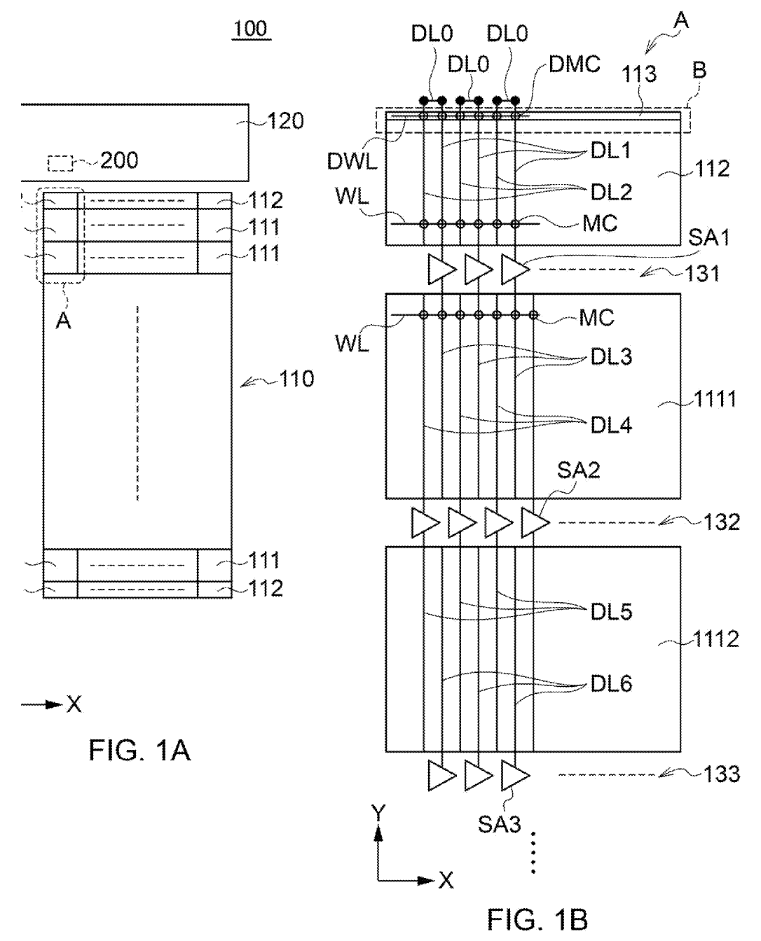

FIG. 1A is a schematic diagram showing a layout of a semiconductor memory device 100 according to one embodiment of the present disclosure. The semiconductor memory device 100 shown in FIG. 1A includes a memory cell array 110, and a peripheral circuit region 120 on which peripheral circuits for controlling the memory cell array 110 are arranged. The memory cell array 110 is constituted of a plurality of memory mats 111 and 112 arranged in a matrix. The memory mats 112 located at ends of the memory cell array 110 in a Y direction are smaller in the size and the capacity than other memory mats 111. The peripheral circuits arranged on the peripheral circuit region 120 include a measurement circuit 200 which will be described later, in addition to an address decoder, a command decoder, a control logic, and the like.

FIG. 1B is a schematic enlarged view of a region A shown in FIG. 1A. The region A includes two memory mats 111 (memory mats 1111 and 1112) and one memory mat 112. The memory mat 112 located at an end includes a plurality of digit lines DL1 and DL2 extending in the Y direction and alternately arranged in an X direction. The X direction and the Y direction may be perpendicular to each other. The memory mat 1111 adjacent to the memory mat 112 includes a plurality of digit lines DL3 and DL4 extending in the Y direction and alternately arranged in the X direction. The memory mat 1112 adjacent to the memory mat 1111 includes a plurality of digit lines DL5 and DL6 extending in the Y direction and alternately arranged in the X direction. Word lines WL extending in the X direction are included in each of the memory mats 111 and 112. A memory cell MC is located at an intersection between an associated one of the word lines WL and an associated one of the digit lines DL. The memory mat 112 located at the end includes also dummy word lines DWL extending in the X direction. A dummy memory cell DMC is located at an intersection between an associated one of the dummy word lines DWL and an associated one of the digit lines DL. The memory mat 111 may also include dummy word lines DWL.

A sense amplifier region 131 on which a plurality of sense amplifiers SA1 are arranged is located between the memory mat 112 and the memory mat 1111. A sense amplifier region 132 on which a plurality of sense amplifiers SA2 are arranged is located between the memory mat 1111 and the memory mat 1112. A sense amplifier region 133 on which a plurality of sense amplifiers SA3 are arranged is located between the memory mat 1112 and a memory mat (not shown) adjacent to the memory mat 1112. Each of the sense amplifiers SA1 is connected to an associated one of the digit lines DL1 and an associated one of the digit lines DL3 and amplifies a potential difference between the digit line DL1 and the digit line DL3. Each of the sense amplifiers SA2 is connected to an associated one of the digit lines DL4 and an associated one of the digit lines DL5 and amplifies a potential difference between the digit line DL4 and the digit line DL5. Each of the sense amplifiers SA3 is connected to an associated one of the digit lines DL6 and an associated one of digit lines not shown in the drawing and amplifies a potential difference between the digit line DL6 and the unshown digit line.

The width in the Y direction of the memory mat 112 located at the end is about a half of the width in the Y direction of each of other memory mats 111. Accordingly, the length in the Y direction of each of the digit lines DL1 and DL2 allocated to the memory mat 112 is about a half of the length in the Y direction of each of the digit lines DL3 to DL6 allocated to other memory mats 111. In an example shown in FIG. 1B, an end of each of the digit lines DL1 in the +Y direction is short-circuited to an end of an associated one of the digit lines DL2 in the +Y direction, whereby a capacitance balance in a pair of digit lines connected to an associated one of the sense amplifiers SA1 is maintained. That is, by short-circuiting of each of the digit lines DL1 to an associated one of the digit lines DL2, the stray capacitance of one of the digit lines (i.e., the digit line DL3) connected to the associated sense amplifier SA1, and the total stray capacitance of the other digit lines DL1 and DL2 connected to the sense amplifier SA1 are balanced. When the total stray capacitance of the digit lines DL1 and DL2 is insufficient, a dummy region 113 may be added to the memory mat 112 located at the end. The dummy region 113 is a region on which dummy memory cells DMC are arranged without any valid memory cells to which a user is accessible being arranged.

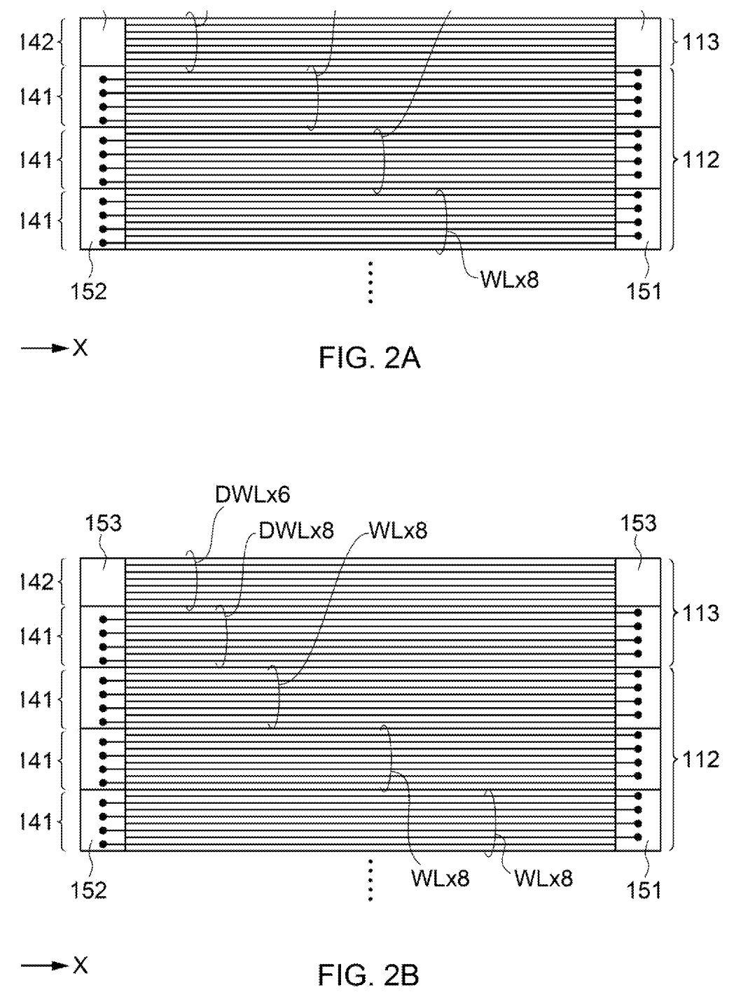

FIGS. 2A and 2B are schematic enlarged views of a region B shown in FIG. 1B. In an example shown in FIG. 2A, a plurality of unit circuits 141 arranged in the Y direction, and a dummy circuit 142 located at an end in the Y direction are included in the region B shown in FIG. 1B. The valid memory mat 112 is constituted of a plurality of unit circuits 141. The dummy circuit 142 is located on the dummy region 113. In the example shown in FIG. 2A, eight word lines WL extending in the X direction, and word driver regions 151 and 152 are included in one unit circuit 141. Four word lines WL allocated to the word driver region 151 and four word lines WL allocated to the word driver region 152 are alternately arranged in the Y direction. In the example shown in FIG. 2A, six dummy word lines DWL and a dummy driver region 153 are included in the dummy circuit 142.

In an example shown in FIG. 2B, one unit circuit 141 is included in the dummy region 113. The unit circuit 141 included in the dummy region 113 includes eight dummy word lines DWL. With this addition of the unit circuit 141 to the dummy region 113, the length of each of the digit lines DL1 and DL2 shown in FIG. 1B correspondingly becomes longer. Therefore, the total stray capacitance of the digit lines DL1 and DL2 can be increased. Circuits located on the word driver regions 151 and 152 of the unit circuit 141 included in the dummy region 113 may be partially different from circuits located on the word driver regions 151 and 152 of other unit circuits 141.

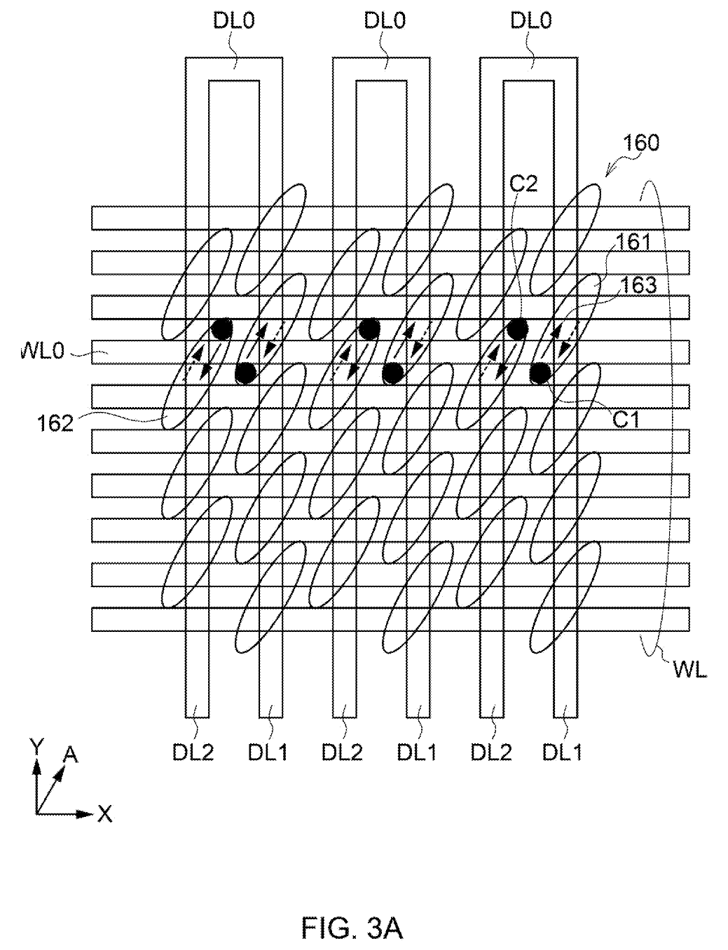

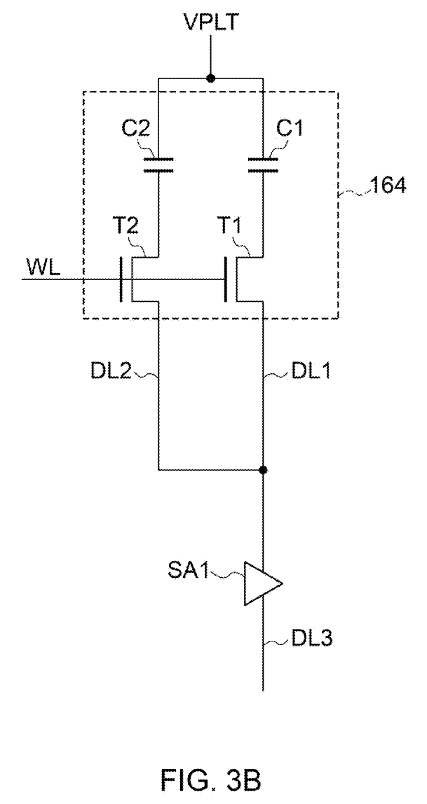

FIG. 3A is a schematic enlarged view for explaining a structure of the memory mat 112 in more detail. As shown in FIG. 3A, a plurality of active regions 160 with the longitudinal direction in an A direction are included in the memory mat 112. Each of the active regions 160 includes a diffusion region 161 positioned at a side in the +A direction, a diffusion region 162 positioned at a side in the -A direction, and a diffusion region 163 positioned at the center in the A direction. Each of the diffusion regions 161 and 162 is connected to an associated one of cell capacitors. Each of the diffusion regions 163 is connected to an associated one of the digit lines DL1 or the digit lines DL2. Each word line WL functions as a gate electrode passing through between the diffusion region 161 and the diffusion region 163 included in an active region 160, and also functions as a gate electrode passing through between the diffusion region 162 and the diffusion region 163 included in another active region 160. Accordingly, for example, when a word line WL0 shown in FIG. 3A is activated, a cell capacitor C1 is connected to an associated one of the digit lines DL1 and a cell capacitor C2 is connected to an associated one of the digit lines DL2. An end of each of the digit lines DL1 in the +Y direction is short-circuited to an end of an associated one of the digit lines DL2 in the +Y direction via a line DL0. An end of each of the digit lines DL1 in the -Y direction is connected to an associated one of the sense amplifiers SA1 as shown in FIG. 1B. In contrast thereto, an end of each of the digit lines DL2 in the -Y direction is open.

FIG. 3B is a circuit diagram of a unit cell 164 included in the memory mat 112. As shown in FIG. 3B, the unit cell 164 included in the memory mat 112 is constituted of two cell transistors T1 and T2 to be selected by a same word line WL, a cell capacitor C1 connected to an associated one of the digit lines DL1 via the cell transistor T1, and a cell capacitor C2 connected to an associated one of the digit lines DL2 via the cell transistor T2. The cell transistor T1 and the cell capacitor C1 constitute one memory cell MC. The cell transistor T2 and the cell capacitor C2 also constitute one memory cell MC. That is, the unit cell 164 included in the memory mat 112 is constituted of two memory cells MC. Of course, same data is written to the two memory cells MC constituting the unit cell 164. In contrast thereto, memory cells MC included in each of other memory mats 111 are independent of each other.

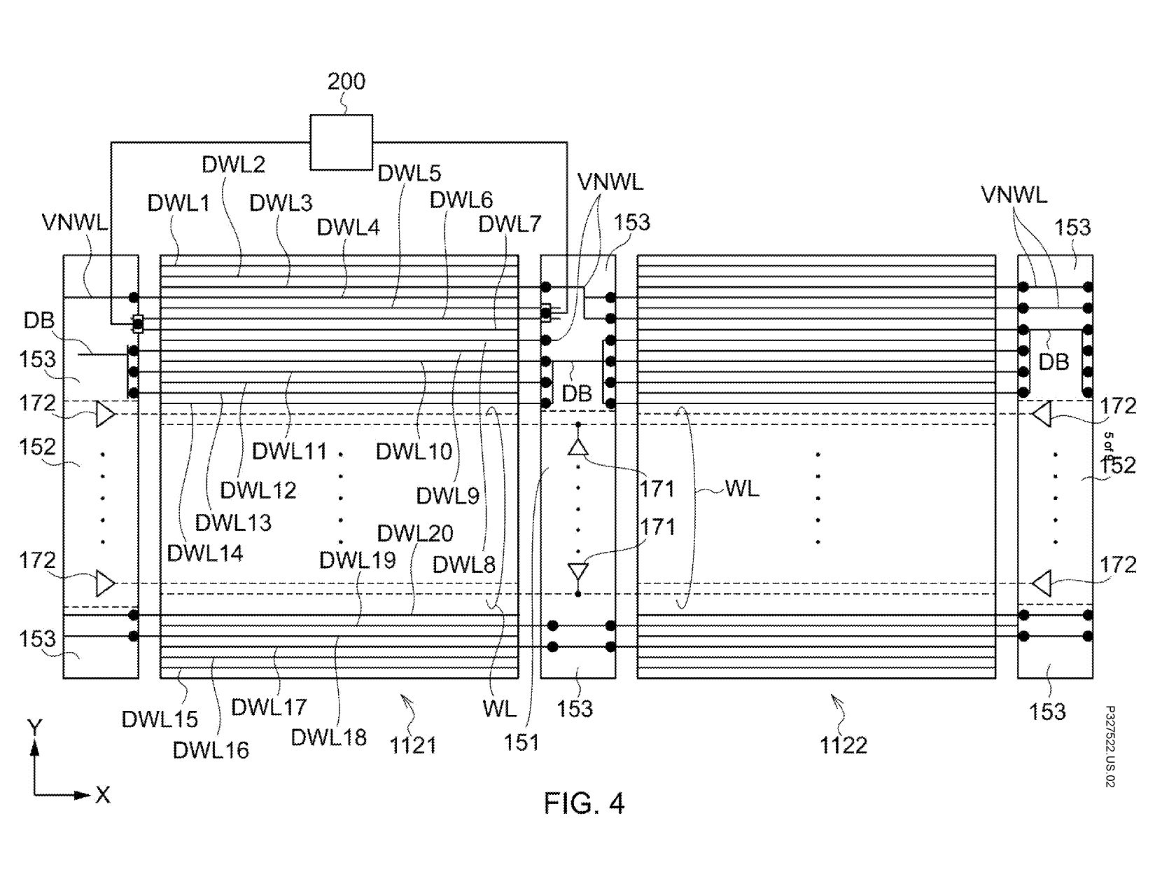

FIG. 4 is a schematic diagram for explaining the dummy word lines DWL included in the memory mats 112 in more detail and shows two memory mats 112 (memory mats 1121 and 1122). In an example shown in FIG. 4, fourteen dummy word lines DWL1 to DWL14 are located at an end of the memory mats 1121 and 1122 in the +Y direction, and six dummy word lines DWL15 to DWL20 are located at an end of the memory mat 112 in the -Y direction. A plurality of word lines WL are located between the dummy word line DWL14 and the dummy word line DWL20. The word lines WL are driven by a word driver circuit 171 located on the word driver region 151 or a word driver circuit 172 located on the word driver region 152.

In the example shown in FIG. 4, the dummy word lines DWL1, DWL2, DWL15, and DWL16 positioned at both ends of the memory mat 1121 in the Y direction are in a floating state without being connected to any circuits included in the dummy driver region 153. The dummy word lines DWL3, DWL4, DWL8, DWL17, and DWL18 are fixed to a potential VNWL by a circuit included in the dummy driver region 153. The potential VNWL is a deactivation level of the word lines WL. The dummy word lines DWL9 to DWL14, DWL19, and DWL20 are applied with a dummy bias potential DB by a circuit included in the dummy driver region 153 in a test mode. The dummy word lines DWL5 to DWL7 are connected to the measurement circuit 200. The measurement circuit 200 is located on the peripheral circuit region 120 as shown in FIG. 1A. Since the memory mats 112 are positioned at the end of the memory cell array 110 in the +Y direction, the line length of a line coupling each of the dummy word lines DWL5 to DWL7 to the measurement circuit 200 is sufficiently short. The dummy word lines DWL4 and DWL8 fixed to the potential VNWL are located at both ends of the dummy word lines DWL5 to DWL7 connected to the measurement circuit 200 in the Y direction. Therefore, even if a short-circuit failure or the like occurs between adjacent dummy word lines, a great current does not flow in the measurement circuit 200.

The memory mat 1121 and the memory mat 1122 may have the same circuit configuration. However, in the example shown in FIG. 4, the dummy word lines DWL3 to DWL6 included in the memory mat 1122 are fixed to the potential VNWL by a circuit included in the dummy driver region 153, and the dummy bias potential DB is applied to the dummy word lines DWL7 to DWL14 included in the memory mat 1122 by a circuit included in the dummy driver region 153 in a test mode.

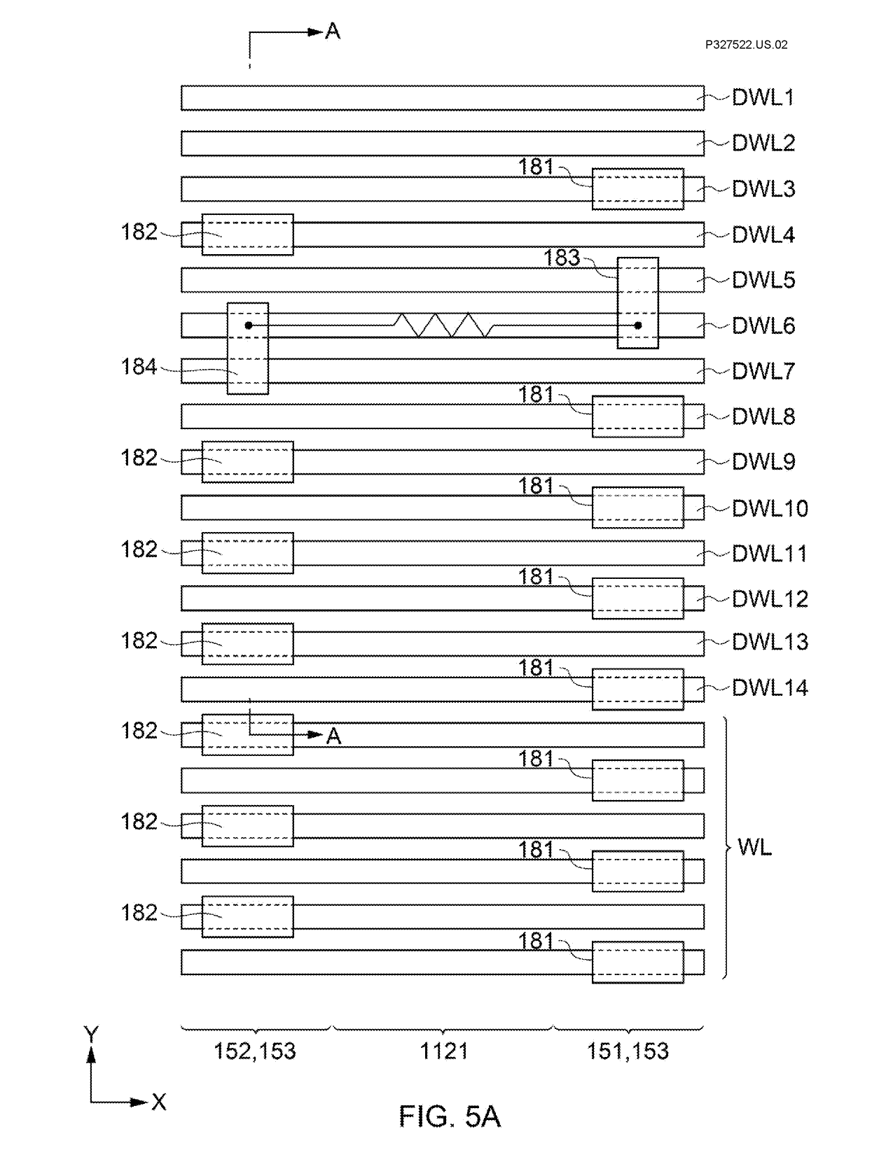

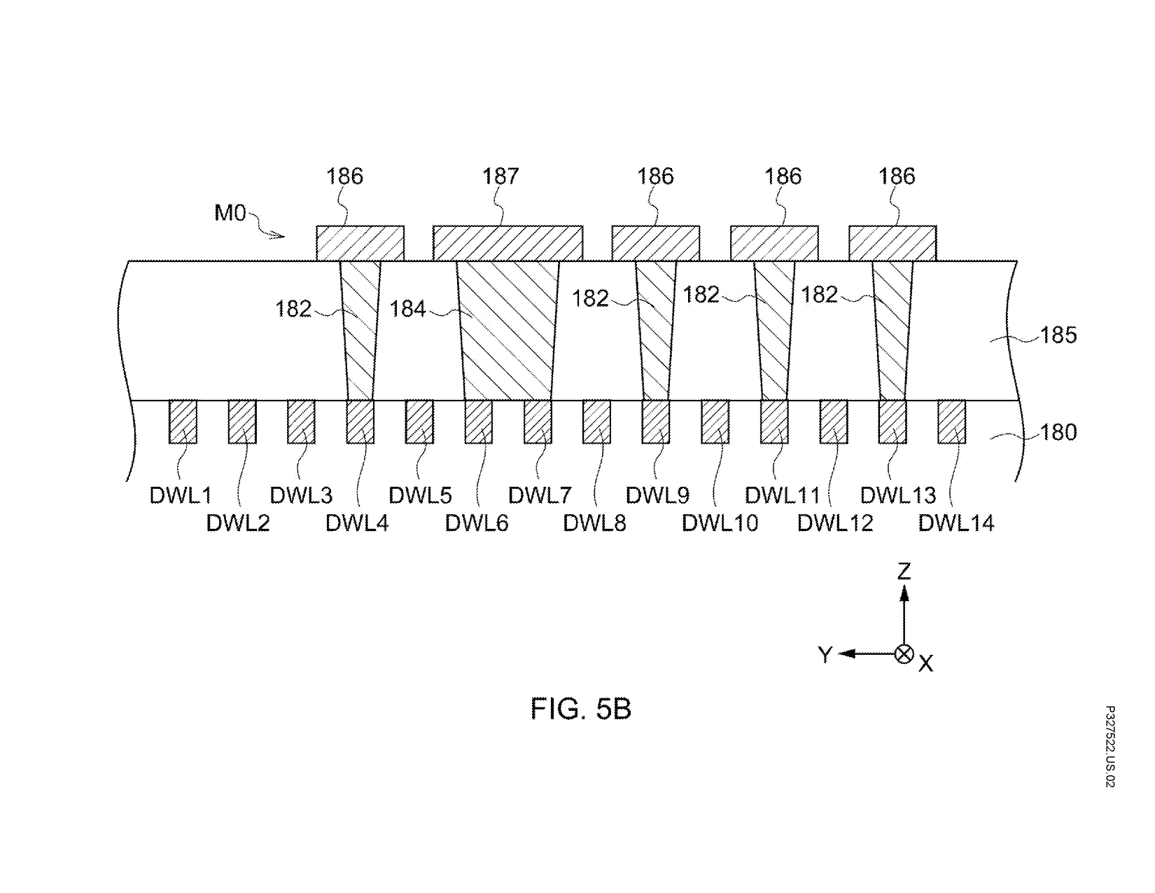

FIG. 5A is a schematic plan view showing contact electrodes allocated to the word lines WL and the dummy word lines DWL1 to DWL14. FIG. 5B is a schematic sectional view along a line A-A shown in FIG. 5A. As shown in FIG. 5B, the dummy word lines DWL1 to DWL14 (and the word lines WL) are embedded in a semiconductor substrate 180. The semiconductor substrate 180 is covered by an interlayer dielectric film 185. The dummy word lines DWL1 and DWL2 located at an end are in a floating state with no contact electrode allocated thereto. In contrast thereto, each of other dummy word lines DWL3 to DWL14 and the word lines WL is connected to a wiring pattern positioned in a wiring layer M0 via an associated contact electrode provided to penetrate through the interlayer dielectric film 185. As shown in FIG. 5A, an end of each of the dummy word lines DWL3, DWL8, DWL10, DWL12, and DWL14 in the +X direction is connected to a wiring pattern positioned in the wiring layer M0 via a contact electrode 181 provided in the dummy driver region 153. An end of each of the dummy word lines DWL4, DWL9, DWL11, and DWL13 in the -X direction is connected to a wiring pattern 186 positioned in the wiring layer M0 via a contact electrode 182 provided in the dummy driver region 153. The contact electrodes 181 and 182 have a size in the X direction larger than that in the Y direction. Accordingly, the contact resistance is decreased and a sufficient distance can be provided between contact electrodes adjacent in the Y direction. An end of each of the dummy word lines DWL3, DWL8, DWL10, DWL12, and DWL14 in the -X direction is open without being connected to another contact electrode. Similarly, an end of each of the dummy word lines DWL4, DWL9, DWL11, and DWL13 in the +X direction is open without being connected to another contact electrode.

In contrast thereto, a contact electrode 183 is allocated to the dummy word lines DWL5 and DWL6 and a contact electrode 184 is allocated to the dummy word lines DWL6 and DWL7. The contact electrode 183 is adjacent in the Y direction to the contact electrode 181 connected to the dummy word line DWL3 and the contact electrode 181 connected to the dummy word line DWL8. The contact electrode 184 is adjacent in the Y direction to the contact electrode 182 connected to the dummy word line DWL4 and the contact electrode 181 connected to the dummy word line DWL9. Each of the contact electrodes 183 and 184 has a size in the Y direction larger than that in the X direction. The size of each of the contact electrodes 183 and 184 in the Y direction may be the same as that of each of the contact electrodes 181 and 182 in the X direction. The size of each of the contact electrodes 183 and 184 in the X direction may be the same as that of each of the contact electrodes 181 and 182 in the Y direction.

Accordingly, the contact electrode 183 is connected in common to ends of the dummy word lines DWL5 and DWL6 in the +X direction, and the contact electrode 184 is connected in common to ends of the dummy word lines DWL6 and DWL7 in the -X direction. As a result, one end of the dummy word line DWL5 is connected to a wiring pattern positioned in the wiring layer M0 via the contact electrode 183, and the other end of the dummy word line DWL5 is connected to a wiring pattern 187 positioned in the wiring layer M0 via the contact electrode 184. Both ends of the dummy word line DWL5 are connected to the measurement circuit 200 shown in FIG. 4. An end of the dummy word line DWL5 in the -X direction is open without being connected to another contact electrode. Similarly, an end of the dummy word line DWL7 in the +X direction is open without being connected to another contact electrode.

Each of the contact electrodes 183 and 184 may have a shape with the size in the X direction larger than that in the Y direction, similarly to other contact electrodes 181 and 182. In this case, the contact electrode 183 is connected only to the end of the dummy word line DWL6 in the +X direction without being connected to the dummy word line DWL5, and the contact electrode 184 is connected only to the end of the dummy word line DWL6 in the -X direction without being connected to the dummy word line DWL7. However, in this case, the distance in the Y direction between the contact electrode 183, and the contact electrode 181 adjacent to the contact electrode 183 and allocated to the dummy word line DWL3 becomes larger than the distance in the Y direction between other contact electrodes. Similarly, the distance in the Y direction between the contact electrode 184, and the contact electrode 181 adjacent to the contact electrode 184 and allocated to the dummy word line DWL9 becomes larger than the distance in the Y direction between other contact electrodes. In this case, the formation density of the contact electrodes in a region on which the contact electrodes 183 and 184 are located is locally changed. In contrast thereto, with the contact electrodes 183 and 184 each having a shape turned by 90 degrees with respect to the contact electrodes 181 and 182 as shown in FIG. 5A, the formation density of the contact electrodes can be kept substantially uniform.

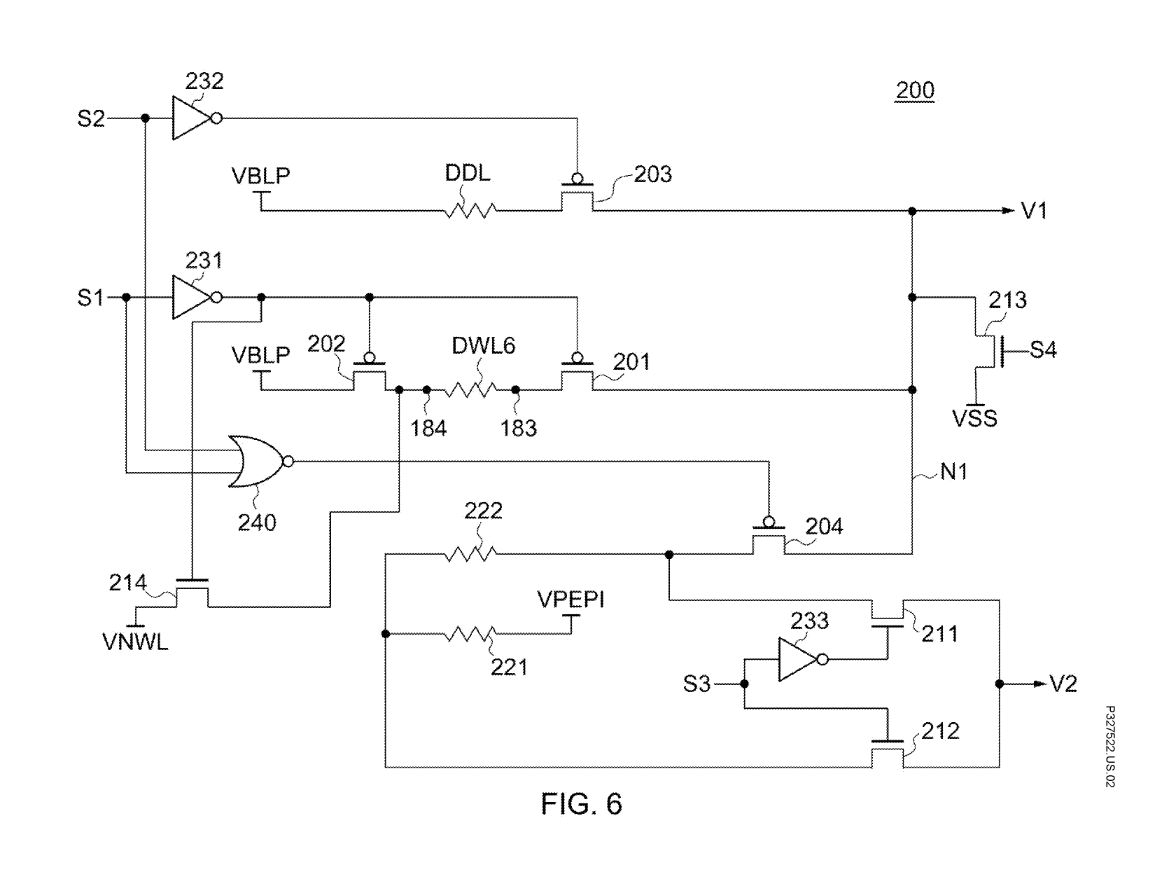

FIG. 6 is a circuit diagram of the measurement circuit 200. The measurement circuit 200 shown in FIG. 6 includes P-channel MOS transistors 201 to 204, N-channel MOS transistors 211 to 214, reference resistors 221 and 222, inverters 231 to 233, and a NOR gate circuit 240. The transistors 201 and 202 are connected to both ends of the dummy word line DWL6 via the contact electrodes 183 and 184, respectively. Accordingly, when a control signal S1 is activated to a high level, a potential VBLP is applied to one end of the dummy word line DWL6 and the other end of the dummy word line DWL6 is connected to a measurement node N1. The potential VBLP is a precharge level of the digit lines DL. Since the transistor 214 is on in a period when the control signal S1 is at a low level, the dummy word line DWL6 is fixed to the potential VNWL that is the deactivation level of the word lines WL via the contact electrode 184. The transistor 203 is connected to a dummy digit line DDL. Accordingly, when a control signal S2 is activated to a high level, the dummy digit line DDL applied with the potential VBLP is connected to the measurement node N1. The reference resistors 221 and 222 are connected in series and a potential VPERI is applied to one end thereof while the other end is connected to the measurement node N1 via the transistor 204. The potential VPERI is an operating potential of peripheral circuits and is higher than the potential VBLP. Therefore, when the control signal S1 or S2 is activated to a high level, a series circuit constituted of the reference resistors 221 and 222 is connected to the measurement node N1.

With this configuration, when the control signal S1 is activated to a high level, a state where the reference resistors 221 and 222 and the dummy word line DWL6 are connected in series and the potential VPERI is applied to one end thereof while the potential VBLP is applied to the other end thereof is obtained. Therefore, a detected potential V1 appearing on the measurement node N1 becomes a level depending on the ratio between the resistance value of the reference resistors 221 and 222 and the resistance value of the dummy word line DWL6. Accordingly, it is possible to measure the actual resistance value of the dummy word line DWL6 by monitoring the detected potential V1 in a state where the control signal S1 is activated.

Similarly, when the control signal S2 is activated to a high level, a state where the reference resistors 221 and 222 and the dummy digit line DDL are connected in series and the potential VPERI is applied to one end thereof while the potential VBLP is applied to the other end thereof is obtained. Therefore, the detected potential V1 appearing on the measurement node N1 becomes a level depending on the ratio between the resistance value of the reference resistors 221 and 222 and the resistance value of the dummy digit line DDL. Accordingly, it is possible to measure the actual resistance value of the dummy digit line DDL by monitoring the detected potential V1 in a state where the control signal S2 is activated.

When a control signal S3 is set to a low level, the transistor 211 is turned on and accordingly a detected potential V2 becomes a level depending on the resistance value of the reference resistors 221 and 222. When the control signal S3 is set to a high level, the transistor 212 is turned on and accordingly the detected potential V2 becomes a level depending on the resistance value of the reference resistor 221. Therefore, the resistance value of the reference resistors 221 and 222 also can be monitored. When a control signal S4 is set to a high level, the transistor 213 is turned on and therefore the measurement node N1 is fixed to a VSS level.

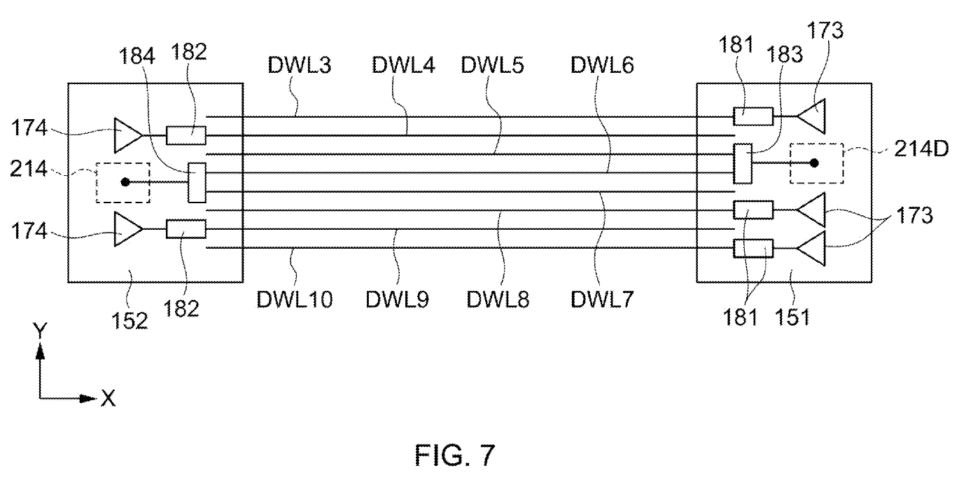

FIG. 7 is a schematic diagram showing one example of circuits connected to the dummy word lines DWL3 to DWL10. In an example shown in FIG. 7, a dummy word driver circuit 173 is connected to each of the dummy word lines DWL3, DWL8, and DWL10 via the contact electrode 181, and a dummy word driver circuit 174 is connected to each of the dummy word lines DWL4 and DWL9 via the contact electrode 182. The dummy word driver circuits 173 and 174 may have the same circuit configuration as that of the word driver circuits 171 and 172 respectively located on the word driver regions 151 and 152. In contrast thereto, the transistor 214 connected in common to the dummy word lines DWL6 and DWL7 via the contact electrode 184 substitutes for a part of the dummy word driver circuits 174 in the word driver region 152. Meanwhile, a dummy transistor 214D that substitutes for a part of the dummy word driver circuits 173 is located on the word driver region 151. The dummy transistor 214D is a transistor that does not actually operate while having the same structure as that of the transistor 214. In this way, the transistor 214 shown in FIG. 6 can be located on the word driver region 152.

As described above, the semiconductor memory device according to the present disclosure includes the contact electrodes 183 and 184 on both ends of the dummy word line DWL6, to enable the dummy word line DWL6 to be connected to the measurement circuit 200 via the contact electrodes 183 and 184. Accordingly, the resistance value of the dummy word line DWL6 can be actually measured using the measurement circuit 200.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a plurality of memory mats each including a plurality of word lines extending in a first direction, a plurality of digit lines extending in a second direction perpendicular to the first direction, and a plurality of memory cells each located at an intersection of an associated one of the plurality of word lines and an associated one of the plurality of digit lines, wherein the plurality of memory mats include a first memory mat located at one end in the second direction, and wherein the plurality of word lines in the first memory mat include a first dummy word line; and
a measurement circuit coupled to one end of the first dummy word line and another end of the first dummy word line and configured to measure a resistance value of the first dummy word line.

2. The apparatus of claim 1, further comprising a first circuit region on which a plurality of word drivers each configured to drive an associated one of the plurality of word lines are arranged,
wherein at least a part of the measurement circuit is arranged in the first circuit region.

3. The apparatus of claim 2, wherein the first circuit region is adjacent to the first memory mat in the first direction.

4. The apparatus of claim 3, further comprising a second circuit region on which a peripheral circuit is arranged,
wherein the first memory mat is adjacent to the second circuit region in the second direction.

5. The apparatus of claim 4, wherein at least a remaining part of the measurement circuit is arranged in the second circuit region.

6. The apparatus of claim 1,
wherein the plurality of word lines in the first memory mat further include a second dummy word line and a third dummy word line,
wherein the first dummy word line is arranged between the second dummy word line and the third dummy word line, and
wherein each of the second and third dummy word lines is fixed to a predetermined potential.

7. The apparatus of claim 6,
wherein the plurality of word lines in the first memory mat further include a fourth dummy word line and a fifth dummy word line,
wherein the first, second, and third dummy word lines are arranged between the fourth dummy word line and the fifth dummy word line,
wherein the fourth dummy word line has no contact plug connected thereon.

8. The apparatus of claim 7, wherein the fifth dummy word lines is configured to be activated in a test mode.

9. The apparatus of claim 1, further comprising a plurality of sense amplifiers arranged in the first direction,
wherein the plurality of memory mats further include a second memory mat,
wherein the plurality of sense amplifiers are arranged between the first memory mat and the second memory mat in the second direction,
wherein each of the plurality of digit lines in the first and second memory mats has a first end located at one side in the second direction and a second end located at another side in the second direction,
wherein the plurality of digit lines in the first memory mat include a plurality of first digit lines and a plurality of second digit lines alternately arranged in the first direction,
wherein the plurality of digit lines in the second memory mat include a plurality of third digit lines,
wherein each of the plurality of sense amplifiers are coupled between the first end of an associated one of the first digit lines and the second end of an associated one of the third digit lines, and
wherein the plurality of third digit lines are longer than the plurality of first and second digit lines.

10. The apparatus of claim 9, wherein the second end of each of the plurality of first digit lines is short-circuited to an associated one of the second end of each of the plurality of second digit lines.

11. An apparatus comprising:
first and second memory mats each including a plurality of word lines extending in a first direction, a plurality of digit lines extending in a second direction perpendicular to the first direction, and a plurality of memory cells each located at an intersection of an associated one of the plurality of word lines and an associated one of the plurality of digit lines;
a plurality of sense amplifiers arranged in the first direction and arranged between the first memory mat and the second memory mat in the second direction; and
a measurement circuit,
wherein the plurality of word lines in the first memory mat include a first word line,
wherein each of the plurality of digit lines in the first and second memory mats has a first end located at one side in the second direction and a second end located at another side in the second direction,
wherein the plurality of digit lines in the first memory mat include a plurality of first digit lines and a plurality of second digit lines alternately arranged in the first direction,
wherein the plurality of digit lines in the second memory mat include a plurality of third digit lines,
wherein each of the plurality of sense amplifiers are coupled between the first end of an associated one of the first digit lines and the second end of an associated one of the third digit lines,
wherein the second end of each of the plurality of first digit lines is short-circuited to an associated one of the second end of each of the plurality of second digit lines, and
wherein the measurement circuit is configured to measure a resistance value of the first word line.

12. The apparatus of claim 11, wherein the plurality of third digit lines are longer in length than the plurality of first and second digit lines.

13. The apparatus of claim 11, wherein the measurement circuit has a first node coupled to one end of the first word line and a second node coupled to another end of the first word line.

14. An apparatus comprising:
a memory mat including a plurality of normal word lines and a plurality of dummy word lines extending in a first direction, a plurality of digit lines extending in a second direction perpendicular to the first direction, a plurality of normal memory cells each located at an intersection of an associated one of the plurality of normal word lines and an associated one of the plurality of digit lines, and a plurality of dummy memory cells each located at an intersection of an associated one of the plurality of dummy word lines and an associated one of the plurality of digit lines; and
a measurement circuit,
wherein the plurality of dummy word lines are arranged between the plurality of normal word lines and at least a part of the measurement circuit in the second direction,
wherein the plurality of dummy word lines include a first dummy word line, and
wherein the measurement circuit is configured to measure a resistance value of the first dummy word line.

15. The apparatus of claim 14, further comprising:
a first contact electrode coupled to one end of the first dummy word line; and
a second contact electrode coupled to another end of the first dummy word line,
wherein the measurement circuit is coupled between the first contact electrode and the second contact electrode.

16. The apparatus of claim 15,
wherein the measurement circuit includes a first transistor coupled to the first contact electrode and a second transistor coupled to the second contact electrode, and
wherein the first dummy word line is located between the first transistor and the second transistor in the first direction.

17. The apparatus of claim 16,
wherein the measurement circuit further includes a reference resistor element having one end coupled to a first power line supplied with a first potential,
wherein the first transistor is coupled between another end of the reference resistor element and the first contact electrode, and
wherein the second transistor is coupled between a second power line supplied with a second potential different from the first potential and the second contact electrode.

18. The apparatus of claim 15,
wherein the plurality of dummy word lines further include a second dummy word line,
wherein the first contact electrode is coupled in common to the one end of the first dummy word line and one end of the second dummy word line, and
wherein another end of the second dummy word line is free from any contact electrode.

19. The apparatus of claim 18,
wherein the plurality of dummy word lines further include a third dummy word line,
wherein one end of the third dummy word line is free from any contact electrode, and
wherein the second contact electrode is coupled in common to the another end of the first dummy word line and another end of the third dummy word line.

20. The apparatus of claim 14,
wherein the plurality of digit lines include a plurality of first digit lines and a plurality of second digit lines alternately arranged in the first direction, and
wherein each of the plurality of first digit lines is short-circuited to an associated one of the plurality of second digit lines.
